(19) United States
(12) Patent Application Publication
(10) Pub. No.: US 2009/0294281 A1
(43) Pub. Date: Dec. 3, 2009

(54) PLASMA FILM FORMING APPARATUS AND FILM MANUFACTURING METHOD

(75) Inventors: Takayuki Moriwaki, Hino-shi (JP); Tomoyasu Saito, Tachikawa-shi (JP); Masao Sasaki, Hachioji-shi (JP); Hitoshi Nakagawara, Tachikawa-shi (JP)

Correspondence Address: FITZPATRICK CELLA HARPER & SCINTO, 1290 Avenue of the Americas, NEW YORK, NY, 10104-3800, US

(73) Assignee: CANON ANELVA CORPORATION, Kawasaki-shi, Kanagawa-ken (JP)

(21) Appl. No.: 12/307,659

(22) PCT Filed: Jul. 4, 2007
(86) PCT No.: PCT/JP2007/063390

§ 371 Date: Jan. 6, 2009

(30) Foreign Application Priority Data
Jul. 7, 2006 (JP) 2006-188521

(51) Int. Cl. C23C 14/48

(52) U.S. Cl. 204/192.38; 204/298.41

(57) ABSTRACT

A plasma film forming apparatus having a plasma gun which emits a plasma beam and a magnet which applies a magnetic field to the plasma beam emitted from the plasma gun to deform the beam section of the plasma beam into an almost rectangular or elliptic shape includes a plurality of magnet units which deflect the plasma beam the beam section of which is deformed, to irradiate an irradiation target with the deflected plasma beam. A first magnet to be arranged on a lower backside to a surface of the irradiation target and a second magnet having magnetic poles which are the same as those of the first magnet are arranged in each magnet unit. The first magnet and the second magnet line up to be spaced apart from each other.

### TECHNICAL FIELD

The present invention relates to a plasma film forming apparatus and, more particularly, to a plasma film forming apparatus of a type that deflects a plasma beam to pull it onto an evaporation material.

### BACKGROUND ART

The production amount of a thin film such as a transparent conductive film ITO, a front surface plate electrode protection layer (e.g., MgO or magnesium oxide), or the like on a large-area substrate for a large-screen display device such as an LCD (Liquid Crystal Display), a PDP (Plasma Display Panel), or the like increases in recent years. As the demand for a high-resolution panel increases, the ion plating method attracts attention as a film forming method that replaces the electron beam (EB) film forming method or sputtering method. The ion plating method can not only realize a high film forming rate, formation of a high-density film, and a large process margin, but also enables film formation on a large-area substrate by controlling the plasma beam by a magnetic field.

In the ion plating method having such advantages, the hollow cathode type ion plating method is particularly promising for film formation on a large-area substrate for a display. In a film forming apparatus employing the hollow cathode type ion plating method, Ar gas is introduced to a plasma gun comprising a hollow cathode and a plurality of electrodes to generate a high-density plasma. The plasma beam is guided to a film forming chamber after its shape and orbit are changed using a magnetic field. The plasma beam generated by the plasma gun extends in a direction perpendicular to the plasma beam irradiation direction, and passes through magnetic fields generated by magnets formed of opposing permanent magnets arranged parallel to each other.

The plasma beam irradiation direction is the direction of an arrow Z in FIG. 1 which passes through the center of the plasma gun and is parallel to the upper surface of an evaporation material pan, and refers to the irradiation direction in which the plasma beam is emitted from the plasma gun before it is deflected. Hence, the plasma beam passing through the magnetic fields forms a sheet-like thin, spreading plasma beam. In this manner, with the pull-in magnets, the plasma beam can irradiate the evaporation material (e.g., MgO) on the evaporation material pan over a wide range. Also, this can heat and evaporate the evaporation material in a wide range to form a film on a large-width substrate (see Japanese Patent Laid-Open No. 9-78230).

In recent years, demands for LCDs and PDPs increase sharply as a flat, large-screen display device that replaces a conventional cathode-ray tube type display device. To further improve the productivity of the LCDs and PDPs is urgently needed. When the hollow cathode type ion plating method described above is to be employed to form a thin film on a large-area substrate for such a large-screen display device, the power of the plasma beam to be injected to the evaporation source must be increased, so that the film forming rate is increased.

### DISCLOSURE OF INVENTION

Problems that the Invention is to Solve

When the injection power of the plasma beam is increased, however, drop-like or fine solid scatterings (evaporation material) called splash may be unexpectedly generated from the evaporation material irradiated with the plasma beam.

The higher the injection power to increase the film forming rate, the larger the generation amount of the splash. The energy of the power-increased plasma beam is focused on the irradiated portion of the evaporation material. This may cause a phenomenon such as bumping at the irradiated portion, thus causing the splash. Therefore, in the conventional plasma film forming apparatus, if scatterings caused by the splash are attached to the surface of the substrate during film formation, they may be undesirably deposited in already formed holes and grooves or on other patterns to form a void and any other defective wiring. Consequently, this considerably degrades the quality of the display apparatus.

### Means of Solving the Problems

The present invention has been made in view of the above problems, and has as its object to prevent splash from occurring without decreasing the film forming rate.

In order to achieve the above object, according to the present invention, there is provided a plasma film forming apparatus having a plasma gun which emits a plasma beam and a magnet which applies a magnetic field to the plasma beam emitted from the plasma gun to deform a beam section of the plasma beam into an almost rectangular or elliptic shape, the apparatus comprising:

a plurality of magnet units which deflect the plasma beam of which the beam section is deformed, to irradiate an irradiation target with the deflected plasma beam,

wherein a first magnet to be arranged on a lower backside to a surface of the irradiation target and a second magnet having magnetic poles which are the same as those of the first magnet are arranged in the magnet units such that the first magnet and the second magnet line up to be spaced apart from each other.

According to the plasma film forming apparatus of the present invention, the first magnet and the second magnet line up along an irradiation direction of the plasma beam.

According to the plasma film forming apparatus of the present invention, the first magnet and the second magnet line up through a yoke.

According to the plasma film forming apparatus of the present invention, the first magnet and the second magnet line up through a third magnet which is arranged on the lower backside to the surface of the irradiation target and has magnetic poles different from those of the first magnet and the second magnet.

According to the plasma film forming apparatus of the present invention, of the first magnet and the second magnet, a magnet arranged farthest from the plasma gun generates the strongest magnetic field.

According to the plasma film forming apparatus of the present invention, the first to third magnets have quadrangular prismatic shapes.

A method of manufacturing a film to be formed on a substrate according to the present invention, the method comprising:
a step of irradiating, in order to evaporate an evaporation material, a plasma generated by a plasma film forming apparatus according to the present invention to the evaporation material serving as an irradiation target which is accommodated in an evaporation material pan arranged in a film forming chamber that can be evacuated, and
a step of forming a film on the substrate arranged in the film forming chamber at a position to oppose the evaporation material pan at a predetermined gap with respect to the evaporation material pan.

According to the plasma film forming apparatus of the present invention, the plurality of magnets to deflect the plasma beam are arranged to be spaced apart from each other along the irradiation direction of the plasma beam such that identical magnetic poles are present on the irradiation target side.

As a result, the plasma beam to irradiate the evaporation material can be dispersed in a wide range to increase the irradiation area of the plasma beam on the evaporation material. Furthermore, the energy density of the plasma beam to irradiate the unit area of the evaporation material can be decreased while the power of the plasma beam is increased to increase the film forming rate. Thus, a plasma film forming apparatus that can prevent splash without lowering the film forming rate can be provided.

Other features and advantages of the present invention will be apparent from the following description taken in conjunction with the accompanying drawings, in which like reference characters designate the same or similar parts throughout the figures thereof.

### BRIEF DESCRIPTION OF DRAWINGS

The accompanying drawings, which are incorporated and constitute a part of the specification, illustrate embodiments of the present invention and, together with the description, serve to explain the principles of the invention.

FIG. 1 is a plan view showing the schematic arrangement of a plasma film forming apparatus according to an embodiment of the present invention;

FIG. 2 is a side view showing the schematic arrangement of the plasma film forming apparatus according to the embodiment of the present invention;

FIG. 3A is a side view showing the schematic arrangement of a pull-in magnet unit according to the embodiment of the present invention;

FIG. 3B is a side view showing the schematic arrangement of a pull-in magnet unit according to another embodiment;

FIG. 3C is a side view showing the schematic arrangement of a pull-in magnet unit according to still another embodiment; and

FIG. 3D is a side view showing the schematic arrangement of a pull-in magnet unit according to still another embodiment.

### BEST MODE FOR CARRYING OUT THE INVENTION

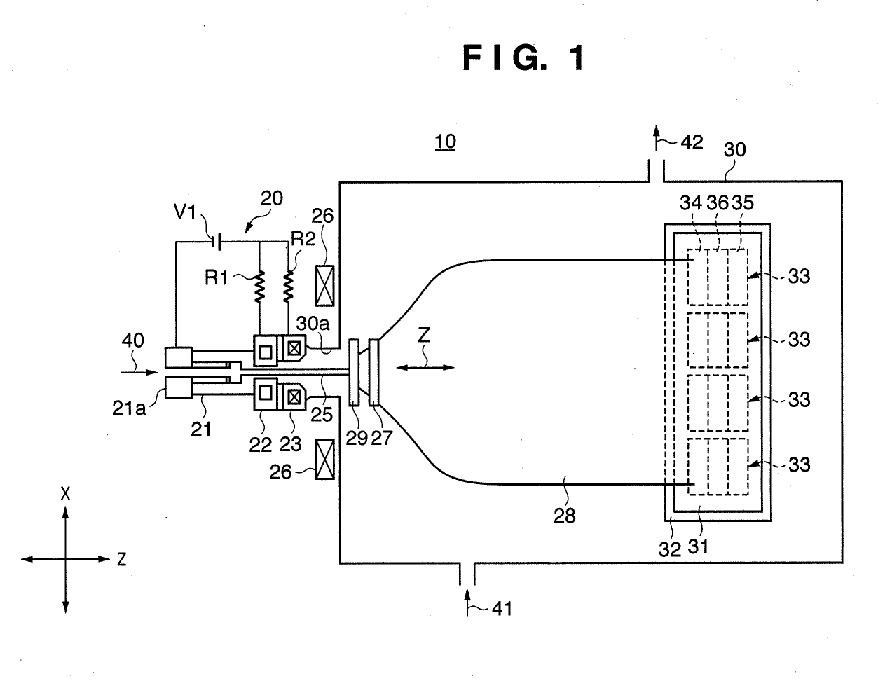

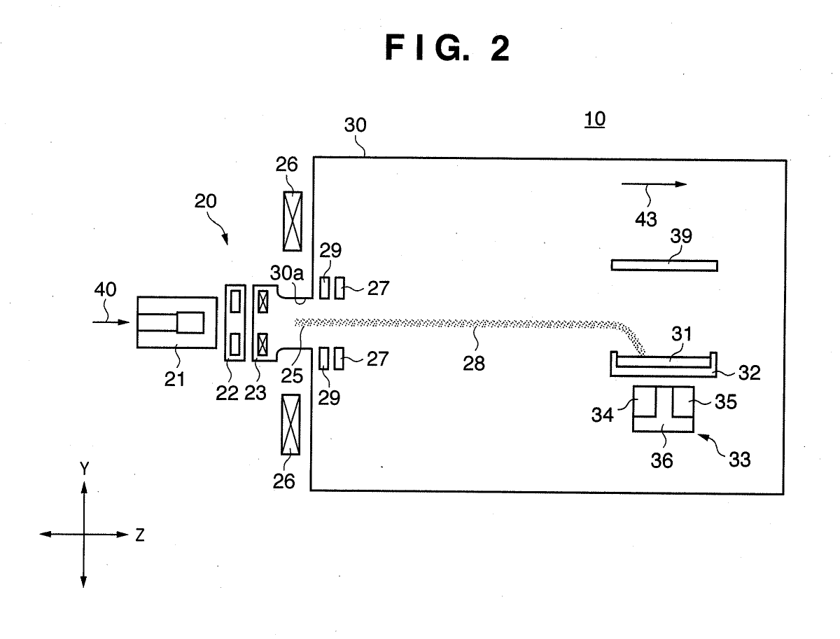

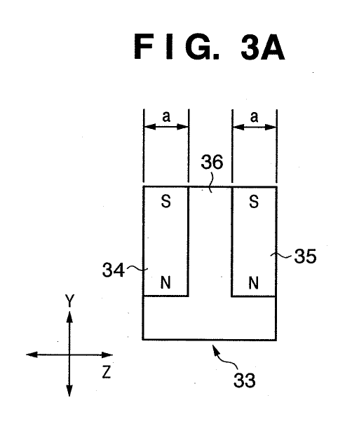

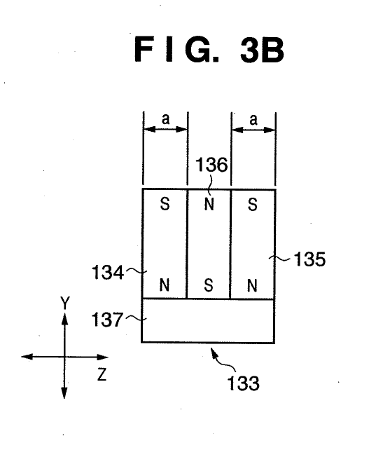

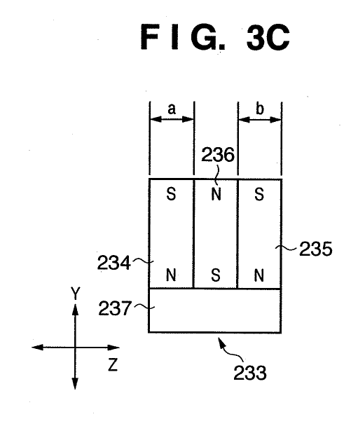

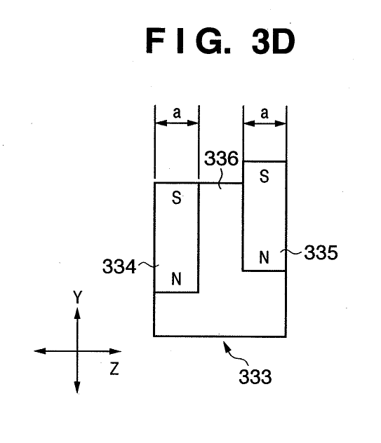

Embodiments of the present invention will be described in detail with reference to FIGS. 1 to FIGS. 3A to 3D. FIG. 1 is a plan view showing the schematic arrangement of a plasma film forming apparatus according to an embodiment of the present invention. FIG. 2 is a side view showing the schematic arrangement of the plasma film forming apparatus according to the embodiment of the present invention. FIG. 3A is a side view showing the schematic arrangement of a pull-in magnet unit according to the embodiment of the present invention.

FIG. 3B is a side view showing the schematic arrangement of a pull-in magnet unit according to another embodiment. FIG. 3C is a side view showing the schematic arrangement of a pull-in magnet unit according to still another embodiment. FIG. 3D is a side view showing the schematic arrangement of a pull-in magnet unit according to still another embodiment.

A plasma film forming apparatus 10 according to this embodiment is a plasma film forming apparatus of a type that deflects a plasma beam 28, obtained by deforming the section of a plasma beam 25 into an almost rectangular or elliptic shape, with magnets 27 and 29 to pull the plasma beam 28 onto an evaporation material 31. Pull-in magnet units 33 to pull the plasma beam 28 onto the evaporation material 31 comprise a plurality of pull-in magnets (first magnets 34 and second magnets 35) which are arranged on the lower backside of an evaporation material pan 32 (irradiation target body) and line up to be spaced apart from each other along the irradiation direction (the direction of an arrow Z) of the plasma beam. This arrangement realizes improvement in productivity while preventing splash from occurring.

As shown in FIGS. 1 and 2, the plasma film forming apparatus 10 according to this embodiment comprises a plasma gun 20, a converging coil 26 to pull the plasma beam from the plasma gun 20 so the plasma beam travels into a film forming chamber 30, and the film forming chamber 30 which accommodates the magnets 27 and 29 to deform the pulled-out plasma beam to have an almost rectangular or elliptic section, the pull-in magnet units 33, the evaporation material pan 32 for holding the evaporation material 31, and a substrate 39. The respective constituent members will be described hereinafter in detail.

The plasma gun 20 comprises a hollow cathode 21, electrode magnet 22, and electrode coil 23. The electrode magnet 22 and electrode coil 23 are arranged on the axis of the hollow cylindrical hollow cathode 21 in this order on the film forming chamber 30 side. The electrode coil 23 is connected to a plasma passing portion 30a extending from the film forming chamber 30. A cathode 21a of the plasma gun 20 is connected to the negative side of a DC power supply V1. The electrode magnet 22 and electrode coil 23 are connected to the positive side of the DC power supply V1 via resistors R1 and R2. In this arrangement, when the DC power supply V1 is operated, a cylindrical plasma beam is generated in the plasma gun 20. Although the plasma gun 20 is arranged outside the film forming chamber 30 in this embodiment, it may be arranged inside the film forming chamber 30. This embodiment exemplifies the plasma film forming apparatus 10 in which one plasma gun 20 is mounted. The present invention can also be applied to a plasma film forming apparatus in which a plurality of plasma guns are mounted in a film forming chamber 30.

The converging coil (air-core coil) 26 is arranged in the plasma gun 20 on a side closer to the film forming chamber 30 than the electrode coil 23 so as to surround the plasma passing portion 30a of the film forming chamber 30. The converging coil 26 is arranged coaxially with the hollow cathode 21. When a DC current is applied to the converging coil 26 from an external power supply (not shown), the plasma beam generated in the plasma gun 20 is pulled into the film forming chamber 30. The plasma beam 25 is pulled out along the extension line (Z direction) of the axis of the hollow cathode 21 and converging coil 26 and travels in the film forming chamber 30.

In the film forming chamber 30, the magnets 29 and 27 are arranged downstream of the radiation direction of the plasma beam 25 sequentially from the upstream side (the plasma gun 20 side) in this order. The magnets 27 and 29 are plate-like permanent magnets extending in a direction perpendicular to the radiation direction of the plasma beam 25, and arranged parallel to each other to oppose each other. While the plasma beam 25 pulled out from the plasma gun 20 into the film forming chamber 30 passes through the magnetic fields generated by the magnets 27 and 29, the plasma beam 25 forms the plasma beam 28 which spreads in a direction (X direction) perpendicular to the radiation direction (Z direction) and has a beam section deformed into an almost rectangular or elliptic shape. Although two sets of magnets 27 and 29 are arranged in this embodiment, the magnet may comprise one set. Alternatively, three or more sets of magnets may be arranged. The magnets 27 and 29 may be arranged outside the film forming chamber 30.

The film forming chamber 30 that can be evacuated accommodates the evaporation material pan 32 which accommodates and holds the evaporation material (e.g., MgO or a transparent conductive film ITO) 31, and the substrate 39 (e.g., a large-size substrate for a display) on which a film is to be formed. The substrate 39 is held by a substrate holder (not shown) and arranged to oppose the evaporation material 31 held by the evaporation material pan 32. The substrate 39 opposes the evaporation material 31 at a predetermined gap determined in accordance with the required specifications, and is conveyed continuously (along an arrow 43 of the Z direction in FIG. 2) to be parallel to the radiation direction (Z direction).

As shown in FIG. 2, in the film forming chamber 30, the plurality of pull-in magnet units 33 are arranged on the lower backside of the evaporation material pan 32 in a direction (X direction) perpendicular to the radiation direction (Z direction) of the plasma beam 25. Each pull-in magnet unit 33 which is shown in detail in FIG. 3A is formed by arranging the pull-in magnet 34 (first magnet) and pull-in magnet 35 (second magnet) having the same quadrangular prismatic shapes (each with a length a in the irradiation direction) from the plasma gun 20 side, that is, along the irradiation direction of the plasma beam 25, and arranging a yoke 36 between the pull-in magnets 34 and 35.

The pull-in magnets 34 and 35 are arranged such that the same magnetic poles, for example, S poles, oppose the evaporation material pan 32. Usually, each of the pull-in magnets 34 and 35 can be formed of, for example, a samarium-cobalt-based magnet (Sm.Co) or a neodymium-based magnet (Nd.Fe.B).

Although the width a of each of the pull-in magnets 34 and 35 in the Z direction is set between 10 mm and 30 mm in this embodiment, it is not particularly limited, and can be freely set considering the material of the pull-in magnet to be used and the required deflecting direction of the plasma beam.

With the above arrangement, the magnetic fields generated by the pull-in magnets 34 and 35 deflect the plasma beam 28 traveling in the film forming chamber 30 to pull the plasma beam 28 onto the evaporation material 31 on the evaporation material pan 32. Thus, the evaporation material 31 is heated and evaporated to form a film on the substrate 39 which opposes the evaporation material 31. According to this embodiment, the pull-in magnets 34 and 35 are arranged to be spaced apart from each other due to the presence of the yoke 36. Thus, a magnetic field by the pull-in magnet 34 and a magnetic field by the pull-in magnet 35 are respectively generated. The magnetic fields generated by the pull-in magnets 34 and 35 disperse the deflecting direction of the plasma beam 28 in the irradiation direction. (Z direction) of the plasma beam 28, so that the evaporation material 31 can be irradiated over a larger range with the plasma beam 28. Hence, even when the power of the plasma beam 25 is increased to improve the productivity such as the film forming rate, the irradiation area of the plasma beam 28 on the evaporation material 31 can be enlarged and a sharp local increase in energy density can be suppressed, thus preventing splash from occurring.

In contrast to this, when only one pull-in magnet is employed and that area of the pull-in magnet which opposes the evaporation material pan 32 is increased, although the magnetic field generated by the pull-in magnet can be made strong, the plasma beam 28 cannot be dispersed because the magnetic field is generated by only one pull-in magnet. Even when the power of the plasma beam 25 is increased, the energy density of the plasma beam 28 may sharply increase locally to cause splash.

In the pull-in magnet unit 33 described above, the yoke 36 is arranged between the pull-in magnets 34 and 35. Alternatively, as shown in FIG. 3B, a pull-in magnet unit 133 may be employed in which a magnet 136 (third magnet) is arranged between two pull-in magnets 134 and 135 (first magnet and second magnet).

The pull-in magnet unit 133 is formed by arranging, from the plasma gun 20 side, the pull-in magnet 134 and 135 having the same quadrangular prismatic shapes (each with a width a in a Z direction) and made of the same material as that of the pull-in magnets 34 and 35 sequentially such that their portions on the evaporation material pan 32 sides are S poles. Furthermore, a magnet 136 (third magnet) is arranged between the pull-in magnets 134 and 135 such that its portion on the evaporation material pan 32 side is an N pole (a magnetic pole different from those of the pull-in magnets 134 and 135). The magnet 136 can be formed of, for example, a samarium-cobalt-based magnet or a neodymium-based magnet. The pull-in magnets 134 and 135 and the magnet 136 are fixed and arranged on a long plate-like yoke 137.

In the pull-in magnet unit 133 having the above arrangement, the pull-in magnets 134 and 135 are arranged to be spaced apart from each other due to the presence of the magnet 136. Thus, a magnetic field by the pull-in magnet 134 and a magnetic field by the pull-in magnet 135 are respectively generated. The magnetic fields generated by the pull-in magnets 134 and 135 disperse the deflecting direction of a plasma beam 28, so that the plasma beam 28 can be dispersed over a larger range of an evaporation material 31. Hence, even when the power of a plasma beam 25 is increased to improve the productivity such as the film forming rate, the radiation area of the plasma beam 28 on the evaporation material 31 can be enlarged and a sharp local increase in energy density can be suppressed, thus preventing splash from occurring.

In place of the yoke 36 or magnet 136 described above, if the two pull-in magnets are merely spaced apart from each other through a gap, the two pull-in magnets respectively generate magnetic fields. Thus, the deflecting direction of the plasma beam 28 can be dispersed, so that the evaporation material 31 can be irradiated over a larger range with the plasma beam 28.

In the pull-in magnet unit 33 described above, the pull-in magnets 34 and 35 are formed of magnets having the same shape. If the magnetic field generated by the magnet 35 located far from the plasma gun 20 is larger than that generated by the pull-in magnet 34 located close to the plasma gun 20, the magnetic field of the pull-in magnet 35 can cover the larger range of the plasma gun 20 side easily, so that the plasma beam 28 can be dispersed more reliably, which is preferable. This can be implemented by forming the pull-in magnet 34 from a samarium-cobalt-based magnet (Sm.Co) and the pull-in magnet 35 from a neodymium-based magnet (Nd.Fe.B) which can generate a magnetic field stronger than that generated by the samarium.cobalt-based magnet, so that a larger magnetic field is obtained with the pull-in magnets 35 than that obtained with the pull-in magnets 34.

As in a pull-in magnet unit 233 shown in FIG. 3C, if the volume of a pull-in magnet 235 (with a length b in the radiation direction) is larger than that of a pull-in magnet 234 (with a length a in the radiation direction) on a plasma gun 20 side (b>a), the magnetic field generated by the pull-in magnet 235 (second magnet) can become larger than that generated by the pull-in magnet 234 (first magnet). In this pull-in magnet unit 233, a magnet 236 (third magnet) is arranged between the pull-in magnets 234 and 235 (first and second magnets), and the pull-in magnets 234 and 235 and the magnet 236 are arranged on a long plate-like yoke 237. Each of the pull-in magnets 234 and 235 and magnet 236 can be formed of, for example, a samarium-cobalt-based magnet (Sm.Co) or a neodymium-based magnet (Nd.Fe.B). In place of the magnet 236, a yoke may be arranged, or a gap may be left between the pull-in magnets 234 and 235.

As in a pull-in magnet unit 333 shown in FIG. 3D, pull-in magnets 334 and 335 may be arranged such that the distal end face of the S pole of the pull-in magnet 335 (second magnet) is closer to an evaporation material pan 32 side (Y direction) than that of the pull-in magnet 334 (first magnet) on a plasma gun 20 side.

This arrangement can increase the proportion of, of the magnetic fields of the pull-in magnets 334 and 335 which are applied to a plasma beam 28, the magnetic field generated by the pull-in magnet 335. This is preferable because the plasma beam 28 can be dispersed more reliably. This pull-in magnet unit 333 is formed by arranging, sequentially from the plasma gun 20 side, the pull-in magnets 334 and 335 (first and second magnets) having the quadrangular prismatic shapes and the identical sections perpendicular to the longitudinal direction, and arranging a yoke 336 between the pull-in magnets 334 and 335. Each of the pull-in magnets 334 and 335 can be formed of, for example, a samarium-cobalt-based magnet (Sm.Co) or a neodymium-based magnet (Nd.Fe.B). The pull-in magnet 335 may be arranged such that the distal end face of its N pole is at almost the same position as the distal end face of the N pole of the pull-in magnet 334. Alternatively, the pull-in magnets 334 and 335 may have the same shape, and the pull-in magnet 335 may be arranged closer to the evaporation material pan 32 side than the pull-in magnet 334.

The plurality of pull-in magnets can comprise three or more pull-in magnets arranged in the irradiation direction of the plasma beam 28 as far as they are spaced apart from each other. In this case, the respective pull-in magnets can naturally be arranged to be spaced apart from each other. Also, the blocks of the pull-in magnets which are arranged adjacent to each other may be spaced apart from each other. Between the pull-in magnets, both a yoke and a magnet with magnetic poles opposite to those of the pull-in magnets may be arranged. The plurality of pull-in magnets need not line up immediately under the plasma beam 25 as far as they are arranged to be spaced apart from each other and can disperse the deflecting direction of the plasma beam 28.

A method of forming a film (a method of manufacturing a film) on the substrate 39 using the plasma film forming apparatus 10 according to this embodiment will be described hereinafter.

First, as shown in FIGS. 1 and 2, the evaporation material 31 is arranged on the evaporation material pan 32 in the film forming chamber that can be evacuated, and the substrate 39 to be subjected to film forming process is set on a substrate holder (not shown).

Then, in order to set the interior of the film forming chamber 30 to a predetermined vacuum degree determined in accordance with the film forming specifications, the interior of the film forming chamber 30 is evacuated (arrow 42), and a reaction gas is supplied into the film forming chamber 30 (arrow 41).

In this state, a plasma beam generating gas (e.g., argon (Ar)) is introduced into the hollow cathode 21 of the plasma gun 20 (arrow 40). When the DC power supply V1 is operated, the magnetic field generated by the converging coil 26 converges the plasma beam 25 generated by the plasma gun 20. The converged plasma beam 25 is pulled out into the film forming chamber 30 while spreading into a cylindrical shape having a specific diameter determined by the current applied to the converging coil 26. The pulled-out plasma beam 25 passes through the magnetic fields generated by the magnets 27 and 29 to form a flat, sheet-like plasma beam 28 which is deformed by the respective magnetic fields to have an almost rectangular or elliptic section.

The plasma beam 28 propagates toward the space sandwiched by the substrate 39 and evaporation material 31, and is deflected by the magnetic fields generated by the pull-in magnets 34 and 35 arranged on the lower backside of the evaporation material pan 32 such that their S poles oppose the evaporation material 31 side, so that the plasma beam 28 is pulled onto the evaporation material 31. That portion of the evaporation material 31 which is heated by the plasma beam 28 is evaporated. The evaporated evaporation material 31 reaches the substrate 39 which is being moved by the substrate holder (not shown) in a direction to separate from the plasma gun 20 (arrow 43), and forms a film (e.g., MgO) on the surface of the substrate 39.

Using the film forming apparatus according to the above embodiment, a magnesium oxide film forming experiment was conducted under the following conditions.

As a pull-in magnet unit for comparison, one having an arrangement identical to that shown in FIG. 3B is used. As an example of the conventional pull-in magnet, only one pull-in magnet with an S pole opposing the lower backside of the evaporation material pan 32 is employed. The distance between the evaporation material pan 32 and the pull-in magnet 134 and that between the evaporation material pan 32 and the pull-in magnet 135 are 80 mm, which is common. The pull-in magnets 134 and 135 and the like have the same shape.

The deposition conditions for magnesium oxide are as follows:
discharge power 0.16 Pa
Ar flow rate 11 sccm
power 26.1 kW
focusing coil current 45 A

Using the film forming apparatus according to the embodiment of the present invention, a magnesium oxide film was formed on the substrate 39 under the above film forming conditions. The irradiation mark (irradiation area) of the plasma beam 28 formed on the evaporation material pan 32 was measured.

Compared to the conventional case which employs one pull-in magnet, when the pull-in magnet unit 133 having the arrangement shown in FIG. 3B was employed, the irradiation area increased by about 1.5 times in the irradiation direction (Z direction in FIGS. 1 and 3B) of the plasma beam 25. Under the above film forming conditions, when one pull-in magnet was employed, splash was generated while a film forming rate of as high as 170 Å/sec was achieved. When the pull-in magnet unit 133 was used, however, a high film forming rate was maintained without generating splash.

The present invention has been described while referring to the above embodiments. Note that the present invention is not limited to the above embodiments and various changes and modifications can be made in the object of improvement or within the spirit and scope of the present invention.

The present invention is not limited to the above embodiments and various changes and modifications can be made without departing from the spirit and scope of the present invention. Therefore, to apprise the public of the scope of the present invention, the following claims are appended.

This application is based upon and claims the benefit of priority from the prior Japanese Patent Application No. 2006-188521, filed Jul. 7, 2006, the entire contents of which are incorporated herein by reference.

1. A plasma film forming apparatus having a plasma gun which emits a plasma beam and a magnet which applies a magnetic field to the plasma beam emitted from said plasma gun to deform a beam section of the plasma beam into an almost rectangular or elliptic shape, the apparatus comprising:
a plurality of magnet units which deflect the plasma beam of which the beam section is deformed, to irradiate an irradiation target with the deflected plasma beam,
wherein a first magnet to be arranged on a lower backside to a surface of the irradiation target and a second magnet having magnetic poles which are the same as those of said first magnet are arranged in said magnet units such that said first magnet and said second magnet line up to be spaced apart from each other,
said first magnet and said second magnet line up along a radiation direction of the plasma beam, and
among said first magnet and said second magnet, a magnet arranged farthest from said plasma gun generates the strongest magnetic field.

2. (canceled)

3. The plasma film forming apparatus according to claim 1, wherein said first magnet and said second magnet line up through a yoke.

4. The plasma film forming apparatus according to claim 1, wherein said first magnet and said second magnet line up through a third magnet which is arranged on the lower backside to the surface of the irradiation target and has magnetic poles different from those of said first magnet and said second magnet.

5. (canceled)

6. The plasma film forming apparatus according to claim 4, wherein said first magnet, said second magnet, and said third magnet have quadrangular prismatic shapes.

7. A method of manufacturing a film to be formed on a substrate, said method comprising:
a step of irradiating, in order to evaporate an evaporation material, a plasma generated by a plasma film forming apparatus according to claim 1 to the evaporation material serving as an irradiation target which is accommodated in an evaporation material pan arranged in a film forming chamber that can be evacuated, and
a step of forming a film on the substrate arranged in the film forming chamber at a position faced to the evaporation material pan at a predetermined gap with respect to the evaporation material pan.

8. The plasma film forming apparatus according to any one of claims 1, 3 and 4, wherein a volume of a magnet arranged farthest from said plasma gun is greater than a volume of a magnet arranged nearest to said plasma gun, thereby among said first magnet and said second magnet, said magnet arranged farthest from said plasma gun generates the strongest magnetic field.

9. The plasma film forming apparatus according to any one of claims 1, 3 and 4, wherein a distance between said irradiation target and a top surface of a magnet arranged farthest from said plasma gun is closer than a distance between said irradiation target and a top surface of a magnet arranged nearest to said plasma gun, thereby among said first magnet and said second magnet, said magnet arranged farthest from said plasma gun generates the strongest magnetic field.
